(19) United States
(12) Patent Application Publication
(10) Pub. No.: US 2016/0208381 A1
(43) Pub. Date: Jul. 21, 2016

(54) THIN FILM ENCAPSULATION MANUFACTURING DEVICE AND METHOD OF MANUFACTURING THIN FILM ENCAPSULATION

(71) Applicant: SAMSUNG DISPLAY CO., LTD., Yongin-City (KR)

(72) Inventors: Seungho Choi, Yongin-City (KR); Jaewon Shim, Yongin-City (KR)

(21) Appl. No.: 14/800,652

(22) Filed: Jul. 15, 2015

(30) Foreign Application Priority Data
Jan. 16, 2015 (KR) 10-2015-0008268

(51) Int. Cl. C23C 16/455; H01L 21/67

(52) U.S. Cl. CPC C23C 16/45544; H01L 21/67207

(57) ABSTRACT

A thin film encapsulation manufacturing device and a method of manufacturing a thin film encapsulation unit are provided. The thin film encapsulation manufacturing device includes: a first buffer unit configured to load a first substrate and a second substrate; a first cluster connected to the first buffer unit and including a first deposition chamber; and a second cluster connected to the first cluster and including a second deposition chamber, wherein the first substrate and the second substrate are alternately input to the first cluster from the first buffer unit, and a first deposition material is deposited on the first substrate in the first deposition chamber, and the first deposition material is deposited on the second substrate in the second deposition chamber.

### CROSS-REFERENCE TO RELATED APPLICATION

This application claims the benefit of Korean Patent Application No. 10-2015-0008268, filed on Jan. 16, 2015 in the Korean Intellectual Property Office, the disclosure of which is incorporated herein in its entirety by reference.

### BACKGROUND

1. Field

Aspects of one or more exemplary embodiments of the present disclosure relate to a thin film encapsulation manufacturing device and a method of manufacturing a thin film encapsulation unit.

2. Description of the Related Art

Mobility-based electronic devices are currently widely used. Mobile electronic devices, such as tablet personal computers (PCs) are currently widely used, in addition to compact electronic devices, such as mobile phones.

Mobile electronic devices, such as those mentioned above, include a display device to provide a user with visual information, such as an image, in order to support various functions. Recently, as components used to drive the display device become more compact, a ratio of a size of the display device to an overall size of an electronic device including the display device is gradually increasing, and a display device having a structure that is bendable from a flat state to a bent state (e.g., bent at a predetermined angle) has recently been developed.

If a display device is formed to be flexible as described above, a light emitting unit of the display device may be encapsulated using a multilayered thin film in consideration of the lifetime or lifespan of the display device. When performing the encapsulation, an encapsulation thin film unit may be formed by alternately stacking an organic layer and an inorganic layer. The organic layer and the inorganic layer may be formed using various methods.

Information disclosed in this Background section was already known to the inventors before achieving the inventive concept or is technical information acquired during the process of achieving the inventive concept. Therefore, it may contain information that does not form the prior art that is already known to the public.

### SUMMARY

One or more exemplary embodiments of the present disclosure include a thin film encapsulation manufacturing device and a method of manufacturing a thin film encapsulation unit in which a process time of the thin film encapsulation manufacturing device is reduced or minimized to improve production capacity.

Additional aspects will be set forth in part in the description which follows and, in part, will be apparent from the description or may be learned by practice of the presented embodiments.

According to one or more exemplary embodiments of the present disclosure, a thin film encapsulation manufacturing device includes: a first buffer unit configured to load a first substrate and a second substrate; a first cluster connected to the first buffer unit and including a first deposition chamber; and a second cluster connected to the first cluster and including a second deposition chamber, wherein the first substrate and the second substrate are alternately input to the first cluster from the first buffer unit, and a first deposition material is deposited on the first substrate in the first deposition chamber, and the first deposition material is deposited on the second substrate in the second deposition chamber.

After the first substrate is deposited in the first cluster, the first substrate may pass through the second cluster, and the second substrate may be deposited in the second cluster after passing through the first cluster.

When a deposition process of the first deposition material in the first deposition chamber is congested, loading of the first substrate into the first cluster may be stopped and the second substrate may be loaded into the first cluster.

The thin film encapsulation manufacturing device may further include a second buffer unit between the first cluster and the second cluster, and the second buffer unit may be configured to load the first substrate or the second substrate that has passed through the first cluster.

When a deposition process of the first deposition material is congested in the second deposition chamber, the first substrate may pass through the second cluster, and the second substrate may be loaded into the second buffer unit.

The first cluster may include a plurality of the first deposition chambers, and the plurality of the first deposition chambers may be individually cleaned during respective cleaning periods.

An initial cleaning period of some of the plurality of the first deposition chambers may be different than an initial cleaning period of the rest of the plurality of the first deposition chambers.

A cleaning period of the some of the plurality of the first deposition chambers and a cleaning period of the rest of the plurality of the first deposition chambers may be substantially the same after an initial cleaning of the plurality of first deposition chambers.

Prior to one of the plurality of the first deposition chambers performing a deposition process, the first substrate may be loaded into another deposition chamber from among the plurality of the first deposition chambers in which a deposition process has been performed.

The thin film encapsulation manufacturing device may further include: a third cluster connected to the second cluster and configured to deposit a second deposition material on one of the first substrate and the second substrate; and a fourth cluster connected to the third cluster and configured to deposit the second deposition material on the other one of the first substrate and the second substrate.

The thin film encapsulation manufacturing device may further include a third buffer unit between the second cluster and the third cluster, and the third buffer unit may be configured to alternately load the first substrate and the second substrate on which the first deposition material has deposited into the third cluster.

According to one or more exemplary embodiments of the present disclosure, a thin film encapsulation manufacturing device includes: a first buffer unit configured to store a first substrate and a second substrate on which an organic emission material has been deposited; a first cluster module including a first cluster and a second cluster, the first cluster being connected to the first buffer unit and including a plurality of first deposition chambers, and the second cluster being connected to the first cluster and including a plurality of second deposition chambers; and a second cluster module including a third cluster and a fourth cluster, the third cluster being connected to the second cluster and including a plurality of third deposition chambers, and the fourth cluster being connected to the third cluster and including a plurality of fourth deposition chambers, wherein the first buffer unit is configured to alternately input the first substrate and the second substrate to the first cluster such that a first deposition material is deposited on the first substrate in one of the first deposition chambers, and the first deposition material is deposited on the second substrate in one of the second deposition chambers.

A second deposition material may be deposited on one of the first substrate and the second substrate in one of the third deposition chambers, and the second deposition material may be deposited on the other one of among the first substrate and the second substrate in one of the fourth deposition chambers.

The first substrate may pass through the second cluster after being deposited in the first cluster, and the second substrate may be deposited in the second cluster after passing through the first cluster.

According to one or more exemplary embodiments of the present disclosure, a method of manufacturing a thin film encapsulation unit, the method including: loading a first substrate and a second substrate, on which an organic emission material is deposited into a first buffer unit; discharging the first substrate from the first buffer unit to a first cluster, and then discharging the second substrate from the first buffer unit to the first cluster; discharging the first substrate from the first cluster after a first deposition material is deposited on the first substrate in a first deposition chamber of the first cluster, and passing the second substrate through the first cluster; loading the first substrate and the second substrate discharged from the first cluster into a second buffer unit; discharging the first substrate and the second substrate from the second buffer unit to a second cluster; and discharging the second substrate from the second cluster after the first deposition material is deposited on the second substrate in a second deposition chamber of the second cluster, and passing the first substrate through the second cluster.

The method may further include determining whether or not a deposition process in the first deposition chamber is congested before discharging the first substrate or the second substrate from the first buffer unit, wherein, when the deposition process in the first deposition chamber is congested, the first buffer unit stops discharging the first substrate and discharges the second substrate.

The method may further include determining whether or not a deposition process in the second deposition chamber is congested before discharging the first substrate or the second substrate from the second buffer unit, wherein, when the deposition process in the second deposition chamber is congested, the second buffer unit stops discharging the second substrate and discharges the first substrate.

### BRIEF DESCRIPTION OF THE DRAWINGS

These and/or other aspects will become apparent and more readily appreciated from the following description of exemplary embodiments, taken in conjunction with the accompanying drawings in which:

FIG. 1 is a conceptual diagram illustrating a deposition apparatus including a thin film encapsulation manufacturing device according to an exemplary embodiment of the present disclosure;

FIG. 2 is a conceptual diagram illustrating a portion of the thin film encapsulation manufacturing device shown in FIG. 1;

FIG. 3 is a flowchart of a method of manufacturing a thin film encapsulation by using the thin film encapsulation manufacturing device shown in FIG. 2;

FIG. 4 is a graph showing a relationship between an interval between inputting of substrates to the thin film encapsulation manufacturing device shown in FIG. 2 and a production time;

FIG. 5 is a graph showing a number of substrates input to the thin film encapsulation manufacturing device shown in FIG. 2 and a standby time of the substrates;

FIG. 6 is a conceptual diagram illustrating a thin film encapsulation manufacturing device according to another exemplary embodiment of the present disclosure; and

FIG. 7 is a cross-sectional view illustrating a substrate manufactured by using the thin film encapsulation manufacturing device illustrated in FIG. 1.

### DETAILED DESCRIPTION

Reference will now be made in detail to exemplary embodiments, examples of which are illustrated in the accompanying drawings, wherein like reference numerals refer to like elements throughout. In this regard, the presented exemplary embodiments may have different forms and should not be construed as being limited to the descriptions set forth herein. Accordingly, exemplary embodiments are merely described below, by referring to the figures, to explain aspects of the present description. As used herein, the term “and/or” includes any and all combinations of one or more of the associated listed items. Expressions, such as “at least one of,” when preceding a list of elements, modify the entire list of elements and do not modify the individual elements of the list.

Because the present disclosure may have various modifications and several embodiments, exemplary embodiments are shown in the drawings and will be described in detail. Aspects, features, and a method of achieving the same will be specified with reference to the embodiments described below in detail together with the attached drawings. However, the embodiments may have different forms and should not be construed as being limited to the descriptions set forth herein. It will be understood that although the terms “first”, “second”, etc. may be used herein to describe various components, these components should not be limited by these terms. These terms are only used to distinguish one component from another. Singular expressions, unless defined otherwise in context, include plural expressions as well. In the following embodiments, it will be further understood that the terms “include,” “including,” “comprise,” “comprising,” and/or “have” used herein specify the presence of stated features or components but do not preclude the presence or addition of one or more other features or components.

It will be understood that when an element or layer is referred to as being “on”, “connected to”, or “coupled to” another element or layer, it may be directly on, connected, or coupled to the other element or layer or one or more intervening elements or layers may also be present. When an element is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements. Further, the use of “may” when describing embodiments of the present invention relates to “one or more embodiments of the present invention”. Also, the term “exemplary” is intended to refer to an example or illustration.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly. As used herein, the terms “use,” “using,” and “used” may be considered synonymous with the terms “utilize,” “utilizing,” and “utilized,” respectively.

The terminology used herein is for the purpose of describing particular example embodiments only and is not intended to be limiting of example embodiments. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

Also, in the drawings, for convenience of description, sizes of elements may be exaggerated or contracted. In other words, because sizes and thicknesses of components in the drawings may be arbitrarily illustrated for convenience of explanation, the following embodiments are not limited thereto. When an embodiment is implementable in another manner, a process order (e.g., a described or predetermined process order) may be different from a described one. For example, two processes that are consecutively described may be concurrently or simultaneously performed or may be performed in an opposite order to the described order.

The controller and/or any other relevant devices or components according to embodiments of the present invention described herein may be implemented utilizing any suitable hardware, firmware (e.g. an application-specific integrated circuit), software, or a suitable combination of software, firmware, and hardware. For example, the various components of the controller may be formed on one integrated circuit (IC) chip or on separate IC chips. Further, the various components of the controller may be implemented on a flexible printed circuit film, a tape carrier package (TCP), a printed circuit board (PCB), or formed on a same substrate as the controller. Further, the various components of the controller may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the exemplary embodiments of the present invention.

Exemplary embodiments of the present disclosure will be described below in more detail with reference to the accompanying drawings. Those components that are the same or are in substantial correspondence are indicated using the same reference numeral regardless of the figure number, and redundant explanations thereof may be omitted.

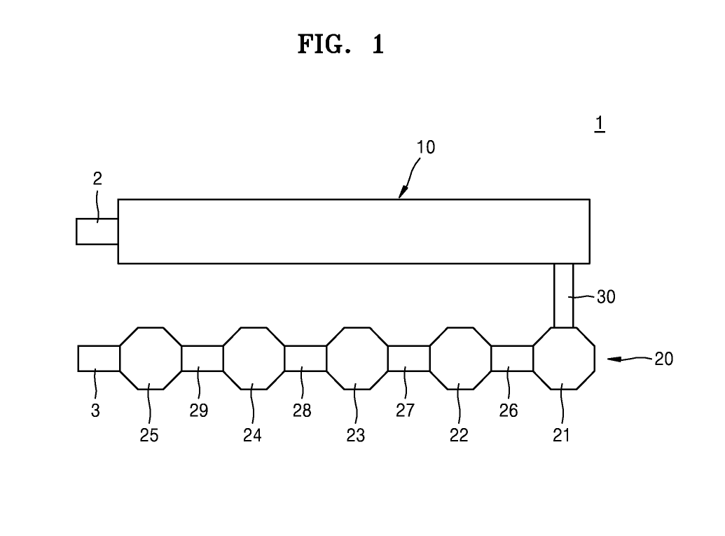

FIG. 1 is a conceptual diagram illustrating a deposition apparatus 1 including a thin film encapsulation manufacturing device 20 according to an exemplary embodiment of the present disclosure.

Referring to FIG. 1, the deposition apparatus 1 may include a display device deposition apparatus 10 and the thin film encapsulation manufacturing device 20. The display device deposition apparatus 10 may be connected to the thin film encapsulation manufacturing device 20 in an in-line manner so that a substrate that has passed through the display device deposition apparatus 10 may be carried to (e.g., carried into) the thin film encapsulation manufacturing device 20.

The display device deposition apparatus 10 is an apparatus for depositing one or more layers which are not formed in each pixel but are formed (e.g., are selectively formed) by patterning, from among layers interposed between a pixel electrode and an opposite electrode of an organic light emitting display device. For example, the display device deposition apparatus 10 may be an apparatus for depositing a red emission layer, a green emission layer, and/or a blue emission layer. A loading unit 2 to which a substrate is carried may be included at an end of the display device deposition apparatus 10.

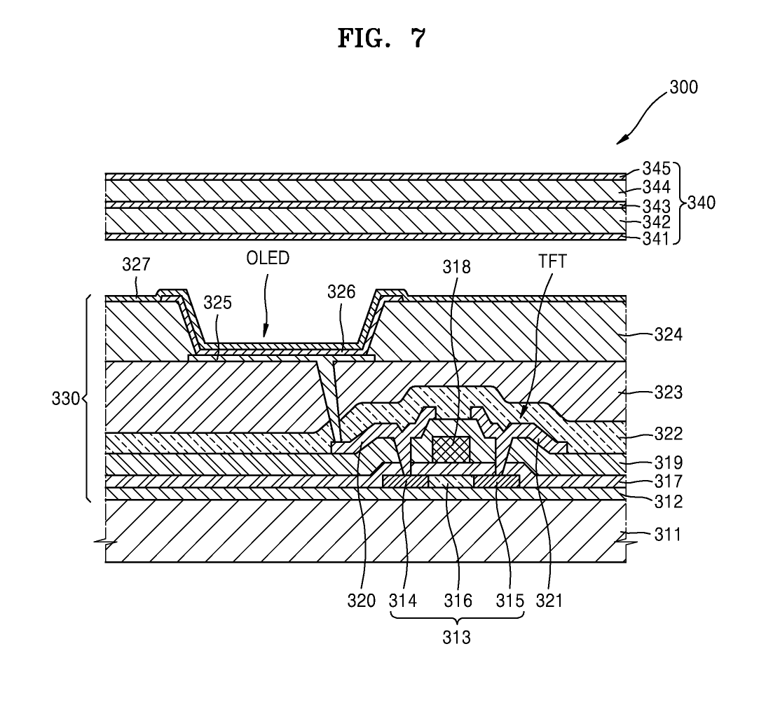

The thin film encapsulation manufacturing device 20 may form an encapsulation unit 340 on an entire surface of an organic light emitting display device, such that the encapsulation unit 340 is a single unit (e.g., is integral) with the organic light emitting display device (see FIG. 7).

The thin film encapsulation manufacturing device 20 may be connected to the display device deposition apparatus 10 via a connection portion 30. The connection portion 30 may be used to allow a thin film encapsulation layer to be deposited (e.g., continuously deposited) on a substrate on which a light emitting unit 330 has been deposited. The connection portion 30 may be in the form of a transport robot having an end effector or in the form of a conveyer.

The thin film encapsulation manufacturing device 20 may include an unloading unit 3 that discharges a substrate on which a thin film process has been completed. After a thin film encapsulation deposition process is completed in a fifth cluster module 25, the substrate may be moved to the unloading unit 3 to be discharged to the outside. A display device is vulnerable to moisture and oxygen, and thus, the deposition apparatus 1 performs a display device deposition process and a thin film encapsulation deposition process while maintaining a vacuum state.

The thin film encapsulation manufacturing device 20 may be formed of a plurality of cluster modules. An encapsulation layer may be formed in each of cluster modules 21 through 25. The number of cluster modules is not limited, and a plurality of cluster modules may be included according to the usage purpose or function of a display device to form a plurality of organic layers and/or inorganic layers. However, for convenience of description, an exemplary embodiment in which first through fifth cluster modules 21 through 25 are included to form organic layers and/or inorganic layers will be described.

An arrangement (e.g., a structure) of the encapsulation unit 340 is determined by a deposition material used as deposition source in the cluster modules 21 to 25, but the present disclosure is not limited to any set or predetermined arrangement. For example, a plurality of organic layers and a plurality of inorganic layers may be alternately stacked, or a plurality of organic layers or inorganic layers may be continuously stacked. However, for convenience of description, the following description will primarily describe an exemplary embodiment in which a first inorganic layer 341, a first organic layer 342, a second inorganic layer 343, a second organic layer 344, and a third inorganic layer 345 are sequentially stacked (see FIG. 7).

The first inorganic layer 341 is formed on a substrate in the first cluster module 21 which is connected to the second cluster module 22 through a first conveyer chamber 26. The first organic layer 342 is formed on the substrate in the second cluster module 22 which is connected to the third cluster module 23 through a second conveyer chamber 27. The second inorganic layer 343 is formed on the substrate in the third cluster module 23 which is connected to the fourth cluster module 24 through a third conveyer chamber 28. The second organic layer 344 is formed on the substrate in the fourth cluster module 24 which is connected to the fifth cluster module 25 via a fourth conveyer chamber 29. The third inorganic layer 345 is formed on the substrate in the fifth cluster module 25 which may discharge the substrate, on which the encapsulation unit 340 has been formed on the light emitting unit 330, to the outside through the unloading unit 3.

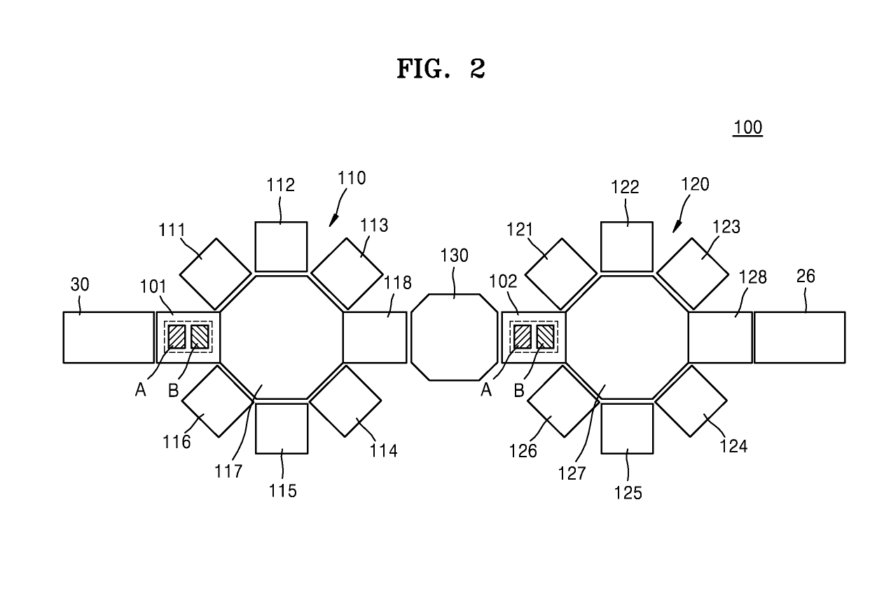

FIG. 2 is a conceptual diagram illustrating a portion of the thin film encapsulation manufacturing device 20 shown in FIG. 1.

Referring to FIG. 2, a first cluster module 100 corresponding to the first cluster module 21 shown in FIG. 1 may include a first buffer unit 101, through which a substrate is loaded to a first cluster 110, and a second buffer unit 102, through which a substrate that has passed through the first cluster 110 is loaded into a second cluster 120. The first cluster 110 and the second cluster 120 are used to deposit a first deposition material on the substrate, and a first connection chamber 130 connects the first cluster 110 and the second cluster 120.

One end of the first buffer unit 101 may be connected to the connection portion 30, and the other end of the first buffer unit 101 may be connected to the first cluster 110. The first buffer unit 101 may load substrates that have passed through the display device deposition apparatus 10 to the first cluster 110. When loading the substrates, the first buffer unit 101 may divide the loaded substrates into first substrates A and second substrates B.

The first buffer unit 101 may alternately load one of the first substrates A and one of the second substrates B into the first cluster 110. For example, the first buffer unit 101 may load one of the second substrates B into the first cluster 110 after one of the first substrates A is loaded into the first cluster 110. Then, the first buffer unit 101 continuously loads the first substrates A into the first cluster 110. A first deposition material may be deposited on the first substrates A in the first cluster 110, and the first deposition material may be deposited on the second substrates B in the second cluster 120. A controller may control the first buffer unit 101 so that the first substrates and the second substrates are alternately input to the first cluster 110.

Also, if a deposition process becomes congested in a plurality of first deposition chambers 111 through 115, the first buffer unit 101 may stop loading the first substrates A into the first cluster 110 and may load only the second substrates B into the second cluster 120.

The first deposition material may be deposited on the first substrates A in the first cluster 110 so that the first inorganic layer 341 is formed on the entire surface of each of the first substrates A. The first cluster 110 may include the first deposition chambers 111 through 115, a first mask stack chamber 116, a first transfer chamber 117, and a first transport chamber 118.

The first deposition chambers 111 through 115 are installed outside (e.g., at a periphery of) the first transfer chamber 117. A number of first deposition chambers is not limited and may be selected according to the desire of the designer. However, for convenience of description, the following description will primarily describe an embodiment in which the first cluster includes five deposition chambers.

The first deposition chambers 111 through 115 may deposit the first deposition material on the first substrates A by using, for example, a sputtering process, a chemical vapor deposition (CVD) process, or an atomic layer deposition (ALD) process.

The first mask stack chamber 116 may store each mask loaded in the first through fifth deposition chambers 111 through 115. The first mask stack chamber 116 may be installed outside the first transfer chamber 117 so that a robot arm of the first transfer chamber 117 may move a mask from the first mask stack chamber 116 to one of the first through fifth deposition chambers 111 through 115.

The first transfer chamber 117 is connected to the first buffer unit 101, the first deposition chambers 111 through 115, the first mask stack chamber 116, and the first transport chamber 118. The first transfer chamber 117 may load the first substrates A into the first deposition chambers 111 through 115 in the first buffer unit 101. Thus, the first inorganic layer 341 may be formed on the first substrates A. Also, the first transfer chamber 117 may move the second substrates B from the first buffer unit 101 to the first transport chamber 118 so that the second substrates B may pass through the first cluster 110.

The second buffer unit 102 is installed between the first connection chamber 130 and the second cluster 120. The second buffer unit 102 may load the first substrates A on which the first inorganic layer 341 is formed and the second substrates B that have passed through the first cluster 110. Also, the second buffer unit 102 may move the first substrates A and the second substrates B to the second cluster 120. The controller may control the second buffer unit 102 so that the first substrates and the second substrates are input to the second cluster 120.

If a deposition process becomes congested at a plurality of second deposition chambers 121 through 125, the second buffer unit 102 may load only the first substrates A into the second cluster 120 and may stop loading the second substrates B into the second cluster 120.

In the second cluster 120, the first deposition material may be deposited on the second substrates B so as to form the first inorganic layer 341 on the entire surface of the second substrates B. The second cluster 120 may include the second deposition chambers 121 through 125, a second mask stack chamber 126, a second transfer chamber 127, and a second transport chamber 128. As elements of the second cluster 120 are the same or substantially the same as the elements of the first cluster 110 described above, a detailed description thereof may be omitted or simplified.

The first cluster 110 and the second cluster 120 may be connected to each other via the first connection chamber 130. The first substrates A or the second substrates B that have passed through the first transport chamber 118 may pass through the first connection chamber 130 to be loaded into the second buffer unit 102.

FIG. 2 conceptually illustrates the first cluster module 100 corresponding to the first cluster module 21 (see FIG. 1). The second cluster module 22, the third cluster module 23, the fourth cluster module 24, and the fifth cluster module 25 may also be formed in a similar manner and/or having a similar structure to the first cluster module 100 (see FIG. 1).

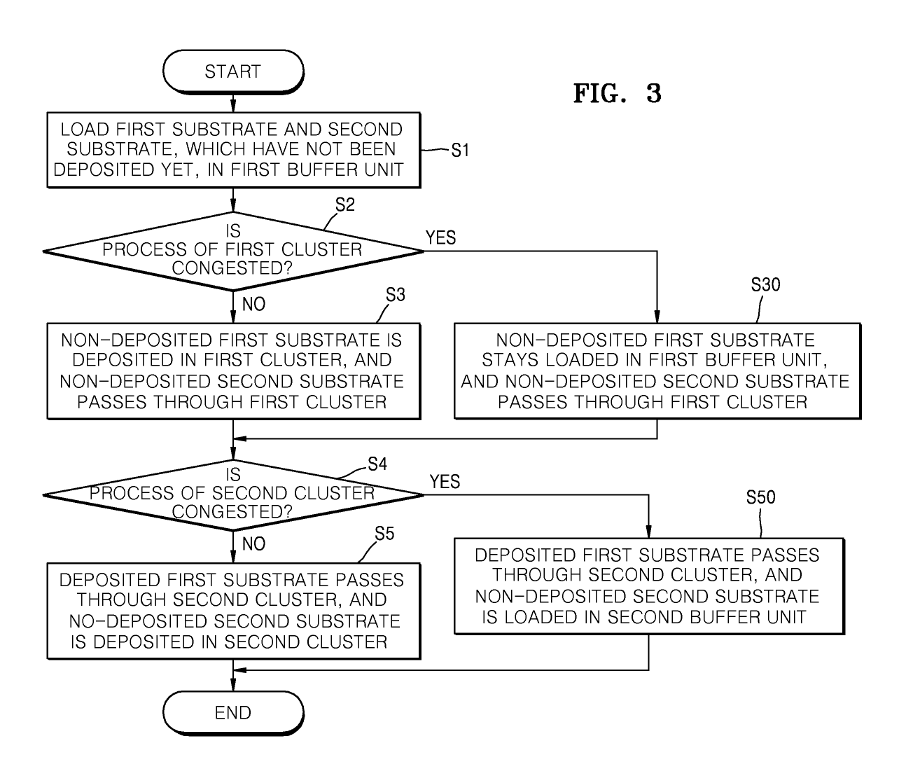

FIG. 3 is a flowchart of a method of manufacturing a thin film encapsulation layer by using the thin film encapsulation manufacturing device shown in FIG. 2.

A method of forming an encapsulation layer by using the thin film encapsulation manufacturing device 20 will be described by referring to FIG. 3.

In operation S1, one of the first substrates A and one of the second substrates B on which an organic emissive material has been deposited may be loaded into the first buffer unit 101. The first substrate A and the second substrate B may be moved from the display device deposition apparatus 10 and loaded into the first buffer unit 101 such that the first substrate A and the second substrate B are separately stacked in the first buffer unit 101.

In operation S2, whether or not a process in the first cluster 110 has become congested may be determined. The first cluster 110 may include the first through fifth deposition chambers 111 through 115, and the first deposition material may be deposited on the first substrate A in one or more of the first through fifth chambers 111 through 115. A sensor installed in the first cluster 110 may sense whether or not a deposition process in each chamber is completed.

When a deposition process in the first deposition chambers 111 through 115 is not (e.g., has not become) congested, the first buffer unit 101 alternately loads the first substrate A and the second substrate B into the first cluster 110 in operation S3. The first substrate A is loaded by the first transfer chamber 117 into one of the first deposition chambers 111 through 115, and the first substrate A, on which deposition has been completed, is moved by the first transfer chamber 117 to the first transport chamber 118 to be loaded into the second buffer unit 102. The second substrate B is directly moved by the first transfer chamber 117 from the first buffer unit 101 to the first transport chamber 118 to be loaded into the second buffer unit 102 (e.g., the second substrate B bypasses the first deposition chambers 111 through 115). For example, the first deposition material is deposited on the first substrate A, loaded into the first cluster 110, in one of the first deposition chambers 111 through 115 so that the first inorganic layer 341 is formed thereon, and deposition is not performed on the second substrate B in the first cluster 110 and the second substrate B is moved (e.g., directly moved) to the second cluster 120.

When a process of the first cluster 110 has become congested, the first buffer unit 101 may not discharge the first substrate A but may discharge the second substrate B in operation S30. For example, the first buffer unit 101 may load only the second substrate B into the second cluster 120 if it is not possible to perform a deposition process in the first deposition chambers 111 through 115 (e.g., if the first deposition chambers 111 through 115 are congested). Accordingly, a deposition process may be flexibly performed in the first cluster module 100, thereby optimizing production capacity.

The first substrate A and the second substrate B discharged from the first cluster 110 may be separately loaded in the second buffer unit 102. While the first inorganic layer 341 is formed on the first substrate A as the first substrate A is deposited in the first cluster 110, no deposition process is performed on the second substrate B, and thus, no encapsulation layer is formed on the second substrate B.

The second cluster 120 may determine whether or not a deposition process has become congested in the second deposition chambers 121 through 125 in operation S4. The second cluster 120 may include the plurality of second deposition chambers 121 through 125 to deposit the first deposition material on the second substrate B. A sensor installed in the second cluster 120 may sense whether or not a deposition process is completed in each chamber.

When a deposition process in the second deposition chambers 121 through 125 is not (e.g., has not become) congested in the second cluster 120, the second buffer unit 102 alternately loads the first substrate A and the second substrate B into the second cluster 120 in operation S5. The first substrate A is directly moved by the second transfer chamber 127 from the second buffer unit 102 to the second transport chamber 128 to be thereby discharged from the first cluster module 100. The second substrate B is loaded into one of the second deposition chambers 121 through 125 by the second transfer chamber 127, and the second substrate B, on which deposition has been completed, is discharged by the second transfer chamber 127 to the second transport chamber 128 so as to be discharged from the first cluster module 100. For example, the first substrate A that is loaded into the second cluster 120 may pass through the second cluster 120, and the first deposition material may be deposited on the second substrate B in one of the second deposition chambers 121 through 125 so that the first inorganic layer 341 is formed thereon.

When a process of the second cluster 120 is congested, the second buffer unit 102 may discharge only the first substrate A to the second cluster 120 and not discharge the second substrate B in operation S50. For example, the first substrate A may pass through the second cluster 120 to complete a process in the first cluster module 100 and may enter the second cluster module 200 corresponding to the second cluster module 22 shown in FIG. 1. When congestion in the second cluster 120 is resolved (e.g., when the process of the second cluster 120 is no longer congested), the second substrate B is loaded into the second cluster 120 so that a deposition process is performed thereon. For example, when a process is not able to be performed in the second deposition chambers 121 through 125, the second buffer unit 102 completes a process on the first substrate A in the first cluster module 100 only and moves the first substrate A to the second cluster module 200. Accordingly, a deposition process may be flexibly performed in the first cluster module 100, thereby increasing and/or optimizing production capacity.

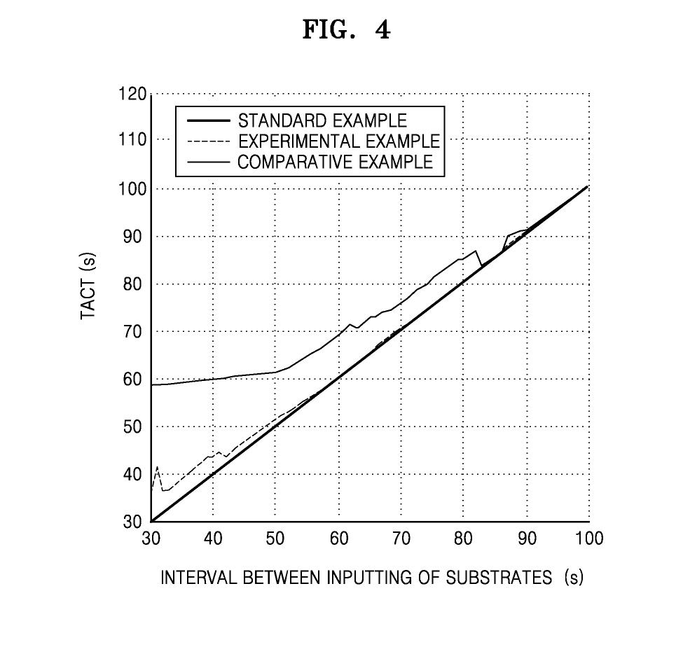

FIG. 4 is a graph showing a relationship between an interval between inputting of substrates to the thin film encapsulation manufacturing device 20 shown in FIG. 1 and a production time.

In FIG. 4, a horizontal axis, denoting an interval between inputting substrates, refers to a time interval at which substrates are input from the display device deposition apparatus 10 to the first cluster module 100. The interval between inputting of substrates may be calculated by measuring a time interval at which substrates are input from the connection portion 30 to the first cluster 110.

A vertical axis, denoting a production process time (TACT TIME), refers to a deposition process time in the first cluster module 100. The production process time refers to a period of time taken for a substrate input to the first cluster 110 to be discharged from the first cluster module 100 after the first inorganic layer 341 is formed on the substrate. The production process time may be calculated by measuring a time interval between substrates that pass through the first transport chamber 118 or the first conveyer chamber 26.

In one experimental example, a deposition process was performed for 230 seconds in the first deposition chambers 111 through 115 to deposit a first deposition material. After a deposition process is performed three times in each chamber, a cleaning process was performed in each chamber for 270 seconds.

A standard example illustrates a relationship between an interval between inputting of substrates and a production process time in an ideal production process. In the ideal production process, the interval between inputting of substrates and the production process time correspond to each other such that a production time may be reduced or minimized and yield of production may be increased or maximized.

A comparative example illustrates a relationship between an interval between inputting of substrates by using a single cluster and a production process time. According to the comparative example, if an interval between inputting of substrates is less than about 90 seconds, the production process time is longer than the interval between inputting of substrates, and thus, a process is or becomes congested in the cluster.

According to the comparative example, if one cluster is included, an arithmetic production process time is about 66 seconds, and when the interval between inputting of substrates is 80 seconds or more, the production process time is synchronized with the interval between inputting of substrates such that the interval between inputting of substrates and the production process time correspond to each other.

An experimental example illustrates a relationship between an interval of inputting substrate by using the first cluster module 100 according to an exemplary embodiment of the present disclosure and a production process time. According to the experimental example, when the interval between inputting of substrates is relatively short, there is a difference from the standard example; however, when the interval between inputting of substrates is about 50 seconds or more, the interval between inputting of substrates and the production process time almost correspond to each other such that an ideal production process may be performed. Thus, the first cluster module 100 may perform a process without substrates becoming congested in the first cluster 110 or the second cluster 120.

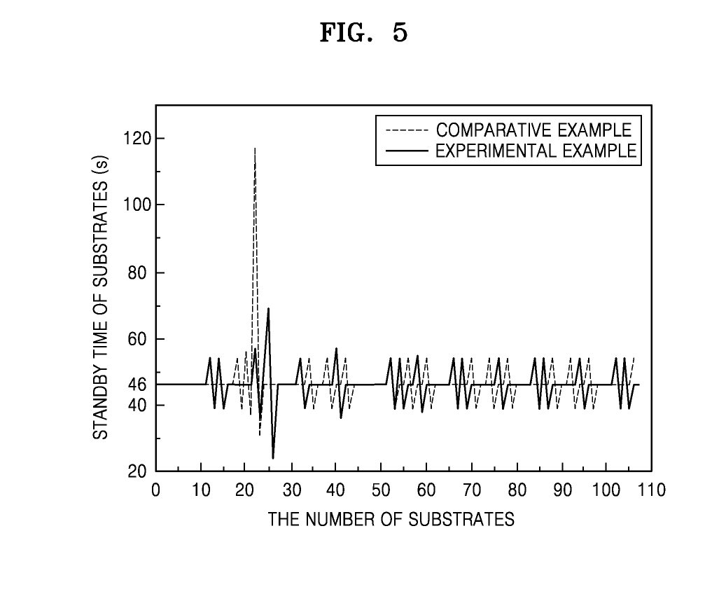

FIG. 5 is a graph showing the number of substrates input to the thin film encapsulation manufacturing device 20 shown in FIG. 2 and a standby time of the substrates.

The first cluster 110 may include a plurality of first deposition chambers 111 through 115, and each chamber may perform cleaning independently. After one or more deposition processes are performed, inner portions of the first through fifth deposition chambers 111 through 115 and a mask may be cleaned. Thus, the first deposition chambers 111 through 115 may have optimized cleaning periods.

If a cleaning process is performed in the first through fifth first deposition chambers 111 through 115 at the same time, a first deposition material may not be deposited in the first cluster 110, thus causing process congestion. As cluster modules are continuously connected to each other in the thin film encapsulation manufacturing device 20, if process congestion occurs in the first cluster module 100, subsequent processes performed after that of the first cluster module 100 may also be congested. Accordingly, the entire process time of the thin film encapsulation manufacturing process may be increased.

Some of the first deposition chambers 111 through 115 may have a relatively short initial cleaning period. For example, some of the first deposition chambers 111 through 115 may have an irregular cleaning period (e.g., an irregular initial cleaning period), and the rest of first deposition chambers 111 through 115 may have a regular cleaning period.

An initial cleaning period of some of the first deposition chambers 111 through 115 is longer than an initial cleaning period of the rest of the first deposition chambers 111 through 115. The cleaning period of some of the first deposition chambers 111 through 115 and the cleaning period of the rest of the first deposition chambers 111 through 115 may become almost same after the initial cleaning period of the first deposition chambers 111 through 115 has passed.

By setting the initial cleaning period of some of the first deposition chambers to be different from an initial cleaning period of the rest of the first deposition chambers, concurrent (e.g., simultaneous) reaching of the cleaning periods of the first deposition chambers 111 through 115 in the first cluster 110 may be prevented to thereby perform processes more efficiently.

A horizontal axis of FIG. 5 denotes the number of substrates loaded into the first cluster 110, and a vertical axis of FIG. 5 denotes a standby time of each substrate when inputting substrates to the first cluster 110 at a time interval of 46 seconds.

A comparative example illustrates an example in which initial cleaning periods of all chambers in the first cluster 110 are set to be the same. That is, all deposition chambers of the first cluster 110 are set to perform a cleaning process after performing a deposition process three times. In the comparative example, if the number of input substrates is about 20, there is no chamber available into which a first substrate or a second substrate may be input. In more detail, a cleaning process may be performed in each chamber of the first cluster 110 and the second cluster 120 or a deposition process may be performed in each chamber and no substrate may enter the first cluster module 100 during that time. Accordingly, substrates are on standby in the connection portion 30 such that a production process time rapidly increases to 93 seconds.

An experimental example illustrates an exemplary embodiment in which some of the first deposition chambers 111 through 115 have a first cleaning period as an initial cleaning period and the rest of the first deposition chambers have a second cleaning period which is shorter than the first cleaning period as an initial cleaning period. Then, a next cleaning period of each of the some of the first deposition chambers 111 through 115 and the rest of the first deposition chambers 111 through 115 were set to the first cleaning period.

For example, the some of the first deposition chambers 111 through 115 have two deposition chambers. A first cleaning period of the some of the first deposition chambers 111 through 115 is set such that cleaning is performed after performing a deposition process twice, and thereafter, cleaning is performed after every third deposition process. A uniform cleaning period of the rest of the first deposition chambers 111 through 115 is set such that cleaning is performed after performing a deposition process three times.

According to the experimental example, initial cleaning periods may be differently set so that not all chambers reach a cleaning period at the same time. By setting initial cleaning periods differently, a deposition process may be continuously performed in the first cluster module 100 so as to reduce or minimize a standby time of the substrates.

According to the thin film encapsulation manufacturing device 20 and the method of manufacturing a thin film encapsulation unit, a plurality of clusters that are connected in-line may be formed, and substrates may be alternately input to each cluster to thereby reduce or minimize a production process time.

According to the thin film encapsulation manufacturing device 20 and the method of manufacturing a thin film encapsulation unit, when a process of any one of the plurality of clusters is congested, a process in the rest of clusters is further performed and the cluster with congestion may be set to convey only substrates on which a process has been completed, thereby flexibly performing a thin film encapsulation process.

According to the thin film encapsulation manufacturing device 20 and the method of manufacturing a thin film encapsulation unit, initial cleaning periods of deposition chambers may be set differently so that not all deposition chambers reach a cleaning period at the same time. As a thin film encapsulation layer is formed on a substrate continuously, a standby time of substrates and a process time for thin film encapsulation may be reduced or minimized according to the thin film encapsulation manufacturing device 20 and the method of manufacturing a thin film encapsulation unit, thereby improving production capacity.

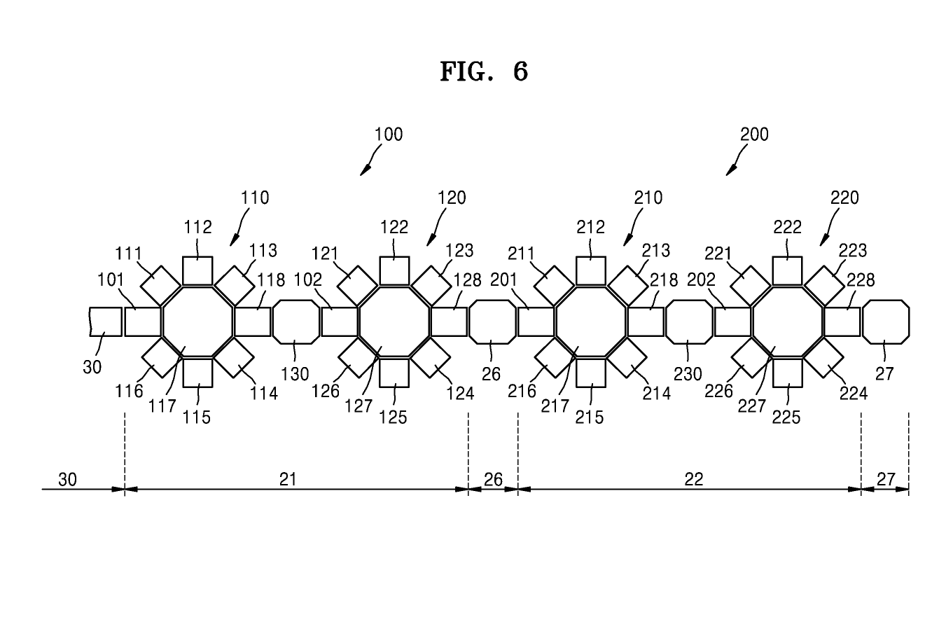

FIG. 6 is a conceptual diagram illustrating a thin film encapsulation manufacturing device 20 according to another exemplary embodiment of the present disclosure.

Referring to FIG. 6, a second cluster module 200 may be connected to the first cluster module 100 and may be used to continuously form an encapsulation layer on the first substrate A and the second substrate B.

The second cluster module 200 may include a third buffer unit 201 for loading a substrate into a third cluster 210 and a fourth buffer unit 202 for loading a substrate into a fourth cluster 220. A first deposition material is deposited on a substrate in the third cluster 210 and the fourth cluster 220, and a second connection chamber 230 connects the third cluster 210 and the fourth cluster 220. As elements of the second cluster module 200 are identical or substantially similar to elements of the first cluster module 100, descriptions thereof may be omitted or simplified.

The second transport chamber 128 of the second cluster 120 may be connected to the first conveyer chamber 26. Also, the first conveyer chamber 26 may be connected to the third buffer unit 201 to connect the first cluster module 100 and the second cluster module 200.

In the first cluster module 100, the first deposition material is deposited on the first substrate A and the second substrate B so that the first inorganic layer 341 is formed on the entire surface of each of the first substrate A and the substrate B. Next, the first substrate A and the second substrate B are loaded into the third buffer unit 201 via the first conveyer chamber 26.

The third buffer unit 201 may load the first substrate A and the second substrate B differently. For example, the third buffer unit 201 may alternately load the first substrate A and the second substrate B into the third cluster 210.

The fourth buffer unit 202 may load the first substrate A and the second substrate B, which have passed through the third cluster 210, differently. For example, the fourth buffer unit 202 may alternately load the first substrate A and the second substrate B into the fourth cluster 220.

One of the first substrate A and the second substrate B is deposited in one of a plurality of third deposition chambers 211 through 215 of the third cluster 210. A second deposition material may be deposited on the one of the first substrate A and the second substrate B in the third deposition chambers 211 through 215 by using a third transfer chamber 217 so that a first organic layer 342 may be formed on the one of the first substrate A and the second substrate B. Next, the one of the first substrate A and the second substrate B may pass through the second connection chamber 230 and the fourth cluster 220 to be moved to the third cluster module 23.

The other of the first substrate A and the second substrate B may pass through the third cluster 210 to enter the fourth cluster 220. The other of the first substrate A and the second substrate B may pass through the third transfer chamber 217 and the second connection chamber 230 to be moved to the fourth cluster 220. The second deposition material may be deposited on the other of the first substrate A and the second substrate B in one of a plurality of fourth deposition chambers 221 through 225 of the fourth cluster 220 to form the first organic layer 342.

According to the thin film encapsulation manufacturing device 20 and the method of manufacturing a thin film encapsulation unit, a plurality of clusters that are connected in-line may be formed, and substrates may be alternately input into each cluster, thereby reducing or minimizing a production process time.

According to the thin film encapsulation manufacturing device 20 and the method of manufacturing a thin film encapsulation unit, when a process of any one of the plurality of clusters is congested, a process in the rest of clusters is further performed and the cluster with congestion may be set to convey only substrates on which a process has been completed, thereby flexibly performing a thin film encapsulation process.

FIG. 7 is a cross-sectional view illustrating a substrate manufactured by using the thin film encapsulation manufacturing device 20 illustrated in FIG. 1.

Referring to FIG. 7, a display substrate 300 may include a first substrate 311, an encapsulation unit 340, and a light emitting unit 330.

The light emitting unit 330 may be formed on the substrate 311. The light emitting unit 330 may include a thin film transistor (TFT), a passivation layer 322 formed to cover the TFT, and an organic light emitting diode (OLED) formed on the passivation layer 322.

The substrate 311 may be formed of a glass material, but is not limited thereto, and may also be formed of a plastic material or a metal material, such as steel use stainless (SUS) or titanium (Ti).

A buffer layer 312 formed of an organic compound and/or an inorganic compound is further formed on an upper surface of the substrate 311 and may be formed of, for example, SiOₓ (x≧1) or SiNₓ (x≧1).

After an active layer 313, arranged in a pattern (e.g., a predetermined pattern), is formed on the buffer layer 312, the active layer 313 is covered by (e.g., buried by) a gate insulation layer 317. The active layer 313 includes a source region 314 and a drain region 315 and further includes a channel region 316 therebetween. The active layer 313 may be formed of amorphous silicon, but is not limited thereto, and may be formed of an oxide semiconductor. For example, the oxide semiconductor may include a metal element of Group 12, 13, or 14, such as zinc (Zn), indium (In), gallium (Ga), tin (Sn), cadmium (Cd), germanium (Ge), and/or hafnium (Hf), and/or an oxide of a material selected from the above-listed group of elements. For example, the active layer 313 formed of a semiconductor may include G-I-Z-O[(In₂O₃)ₐ(Ga₂O₃)_{b}(ZnO)_{c}] (where a, b, and c are real numbers respectively satisfying conditions of a≧0, b≧0, and c>0). However, for convenience of description, the following description will primarily focus on an exemplary embodiment in which the active layer 313 is formed of amorphous silicon.

The active layer 313 may be formed by forming an amorphous silicon layer on the buffer layer 312, crystallizing the same to form a polysilicon silicon layer, and patterning the polysilicon silicon layer. The source and drain regions 314 and 315 of the active layer 313 are doped with an impurity according to a desired TFT type or kind, such as a driving TFT or a switching TFT.

A gate electrode 318 corresponding to the active layer 313 and an interlayer insulating layer 319 covering the gate electrode 318 are formed on an upper surface of the gate insulation layer 317.

Then, a contact opening (e.g., a contact hole) is formed in the interlayer insulating layer 319 and the gate insulating layer 317, and a source electrode 320 and a drain electrode 321 are formed on the interlayer insulating layer 319 to respectively contact the source region 314 and the drain region 315.

The source and drain electrodes 320 and 321 may be formed of a material having excellent electrical conductivity and to have a thickness that facilitates a light reflecting function. For example, the source and drain electrodes 320 and 321 may be formed of a metal material, such as Ag, Mg, Al, Pt, Pd, Au, Ni, Nd, Ir, Cr, Li, Ca, or a compound of these.

The passivation layer 322 may be formed on the source electrode 320 and the drain electrode 321. The passivation layer 322 may be formed of an inorganic layer, such as a silicon oxide or a silicon nitride, or an organic layer.

A planarization layer 323 may be formed on the passivation layer 322. The planarization layer 323 includes an organic layer, such as acryl, polyimide, or benzocyclobutene (BCB).

A pixel electrode 325 of the OLED is formed on the passivation layer 322. The pixel electrode 325 contacts the drain electrode 321 of the TFT through a via opening (e.g., a via hole) formed in the passivation layer 322 and the planarization layer 323. The passivation layer 322 may be formed of an inorganic material and/or an organic material and as a single layer or having a multilayer structure. The passivation layer 322 may be formed of a planarization layer such that an upper surface thereof is planar regardless of curves at a lower layer thereof or may also be formed as a curved layer that is curved according to curves at a lower layer thereof. Also, the passivation layer 322 may be formed of a transparent insulating material so as to achieve resonating effects.

After forming the pixel electrode 325 on the passivation layer 322, a pixel defining layer 325 is formed of an organic material and/or an inorganic material to cover the pixel electrode 325 and the passivation layer 322, and an opening is formed in the pixel defining layer 324 to expose the pixel electrode 325.

Also, an organic layer 326 and an opposite electrode 327 are at least formed on the pixel electrode 325.

The pixel electrode 325 functions as an anode, and the opposite electrode 327 functions as a cathode, but polarities of the pixel electrode 325 and the opposite electrode 327 may be exchanged.

The pixel electrode 325 may be formed of a material having a high work function, for example, of a transparent conductor, such as ITO, IZO, In₂O₃, or ZnO.

The opposite electrode 327 may be formed of a material having a low work function, for example, a metal, such as Ag, Mg, Al, Pt, Pd, Au, Ni, Nd, Ir, Cr, Li, Ca, or a compound of these. For example, in one embodiment, the opposite electrode 327 is formed of Mg, Ag, or Al and to have a small thickness so as to function as a semi-transmissive reflection layer and so that light is transmitted therethrough after optical resonance.

The pixel electrode 325 and the opposite electrode 327 are insulated from each other by the organic layer 326 (e.g., an organic emission layer), and voltages of different polarities from each other may be applied to the organic layer 326 so that light is emitted from the organic layer 326.

The organic layer 326 may be a low-molecular weight organic layer or a polymer organic layer. When a low-molecule organic layer is used, the organic layer 326 may include a hole injection layer (HIL), a hole transport layer (HTL), an organic emission layer (EML), an electron transport layer (ETL), and/or an electron injection layer (EIL) in a single or complex (e.g., stacked) structure. Examples of organic materials include copper phthalocyanine (CuPc), N,N′-Di(naphthalene-1-yl)-N,N′-diphenylbenzidine (NPB), and tris-8-hydroxyquinoline aluminum (Alq3). The low-molecular weight organic layer is formed using a vacuum deposition method. The HIL, HTL, ETL, EIL, and the like are common layers and may be commonly applied to red, green, and/or blue pixels. Accordingly, similar to the opposite electrode 327, the common layers may be formed to cover all of the pixels.

When a polymer organic layer is used, the polymer organic layer may typically have a structure including a HTL and an EML, and poly(3,4-ethylenedioxythiophene) (PEDOT) may be used as the HTL, and a polymer organic material, such as poly(p-phenylene vinylene) (PPV)-based or polyfluorene-based material, is used as the organic emission layer. The polymer organic layer may be formed by using a screen printing method, an inkjet printing method, a fine metal mask process, a laser thermal printing method, or the like.

The organic emission layer may be variously formed. For example, a blue organic emission layer, a green organic emission layer, and a red organic emission layer may be formed beside each other in each sub-pixel to form one unit pixel. Instead of forming a blue organic emission layer, a green organic emission layer, and a red organic emission layer, an organic emission layer of other colors may also be formed in a sub-pixel. For example, besides a blue organic emission layer, a green organic emission layer, and a red organic emission layer being formed beside each other in a sub-pixel, one unit pixel may also be formed by stacking a blue organic emission layer, a green organic emission layer, and a red organic emission layer on one another to form a white organic emission layer as a sub-pixel.

While an organic emission layer is formed for each pixel and of an individual light emitting material in the above-described exemplary embodiment, exemplary embodiments of the present disclosure are not limited thereto. An organic emission layer may be commonly formed with respect to all pixels regardless of positions of the pixels. An organic emission layer may be formed, for example, by vertically stacking layers including emissive materials emitting red, green, and blue light or mixing the layers. When white light is to be emitted, other color combinations are also possible. Also, a color converting layer converting the emitted white light to a color (e.g., a predetermined color) or a color filter may be further included.

The organic layer 326 is not limited to the above-described organic emission layer. However, for convenience of description, the following description will primarily focus on an embodiment in which a blue organic emission layer, a green organic emission layer, and a red organic emission layer are formed as sub-pixels to form a single unit pixel.

As described above, the light emitting unit 330 may be formed on the substrate 311 by using the display device deposition apparatus 10, and then the substrate 311 on which the light emitting unit 330 is formed may enter the thin film encapsulation manufacturing device 20 so that the thin film encapsulation unit 340 is formed on the light emitting unit 330. In one embodiment, the encapsulation unit 340 may be formed by sequentially stacking the first inorganic layer 341, the first organic layer 342, the second inorganic layer 343, the second organic layer 344, and the third inorganic layer 345 as described above.

For example, the first organic layer 342 and the second organic layer 344 may be formed of a polymer and of a single layer or having a stacked layer structure including polyethylene terephthalate, polyimide, polycarbonate, epoxy, polyethylene, and/or polyacrylate. In one embodiment, the first organic layer 342 and the second organic layer 344 may be formed of polyacrylate, or of a material such as a polymerized monomer composition including a diacrylate based monomer and a triacrylate based monomer. The monomer composition may further include a monoacrylate based monomer. Also, a photo-initiator well-known in the related art, such as 2,4,6-trimethylbenzoyl-diphenyl-phosphineoxide (TPO), may be further included in the monomer composition, but the monomer composition is not limited thereto and the monomer composition may also include epoxy, polyimide, polyethylene terephthalate, polycarbonate, polyethylene, and/or polyacrylate.

The first inorganic layer 341, the second inorganic layer 343, and the third inorganic layer 345 may each be a single layer or have a stacked layer structure including a metal oxide or a metal nitride. For example, the first inorganic layer 341, the second inorganic layer 343, and the third inorganic layer 345 may include silicon oxide (SiO₂), silicon nitride (SiNₓ), aluminum oxide (Al₂O₃), titanium oxide (TiO₂), zirconium oxide (ZrOₓ), and/or zinc oxide (ZnO). The third inorganic layer 345, which is an uppermost layer, may be formed to prevent or protect from penetration of moisture into the light emitting unit 330.

Also, the second organic layer 344 may have a smaller area than the third inorganic layer 345. The second organic layer 344 may be completely covered by the second inorganic layer 343.

As described above, according to the thin film encapsulation manufacturing device and the method of manufacturing a thin film encapsulation unit of one or more of the above exemplary embodiments, congestion of substrates in clusters may be reduced to reduce or minimize a process time, thereby improving production capacity.

It should be understood that the exemplary embodiments described herein should be considered in a descriptive sense only and not for purposes of limitation. Descriptions of features or aspects within each exemplary embodiment should typically be considered as available for other similar features or aspects in other exemplary embodiments.

While one or more exemplary embodiments have been described with reference to the figures, it will be understood by those of ordinary skill in the art that various changes in form and details may be made therein without departing from the spirit and scope as defined by the following claims and their equivalents.

What is claimed is:

1. A thin film encapsulation manufacturing device comprising:
a first buffer unit configured to load a first substrate and a second substrate;
a first cluster connected to the first buffer unit and comprising a first deposition chamber; and
a second cluster connected to the first cluster and comprising a second deposition chamber,
wherein the first substrate and the second substrate are alternately input to the first cluster from the first buffer unit, and
wherein a first deposition material is deposited on the first substrate in the first deposition chamber, and the first deposition material is deposited on the second substrate in the second deposition chamber.

2. The thin film encapsulation manufacturing device of claim 1, wherein, after the first substrate is deposited in the first cluster, the first substrate passes through the second cluster, and
wherein the second substrate is deposited in the second cluster after passing through the first cluster.

3. The thin film encapsulation manufacturing device of claim 1, wherein, when a deposition process of the first deposition material in the first deposition chamber is congested, loading of the first substrate into the first cluster is stopped and the second substrate is loaded into the first cluster.

4. The thin film encapsulation manufacturing device of claim 1, further comprising a second buffer unit between the first cluster and the second cluster, and
wherein the second buffer unit is configured to load the first substrate or the second substrate that has passed through the first cluster.

5. The thin film encapsulation manufacturing device of claim 4, wherein, when a deposition process of the first deposition material is congested in the second deposition chamber, the first substrate passes through the second cluster and the second substrate is loaded into the second buffer unit.

6. The thin film encapsulation manufacturing device of claim 1, wherein the first cluster further comprises a plurality of the first deposition chambers, and
wherein the plurality of the first deposition chambers are individually cleaned during respective cleaning periods.

7. The thin film encapsulation manufacturing device of claim 6, wherein an initial cleaning period of some of the plurality of the first deposition chambers is different than an initial cleaning period of the rest of the plurality of the first deposition chambers.

8. The thin film encapsulation manufacturing device of claim 7, wherein a cleaning period of the some of the plurality of the first deposition chambers and a cleaning period of the rest of the plurality of the first deposition chambers is substantially the same after an initial cleaning of the plurality of the first deposition chambers.

9. The thin film encapsulation manufacturing device of claim 6, wherein, prior to one of the plurality of the first deposition chambers performing a deposition process, the first substrate is loaded into another deposition chamber from among the plurality of the first deposition chambers in which a deposition process has been performed.

10. The thin film encapsulation manufacturing device of claim 1, further comprising:
a third cluster connected to the second cluster and configured to deposit a second deposition material on one of the first substrate and the second substrate; and
a fourth cluster connected to the third cluster and configured to deposit the second deposition material on the other one of the first substrate and the second substrate.

11. The thin film encapsulation manufacturing device of claim 10, further comprising a third buffer unit between the second cluster and the third cluster,
wherein the third buffer unit is configured to alternately load the first substrate and the second substrate on which the first deposition material has been deposited into the third cluster.

12. A thin film encapsulation manufacturing device comprising:
a first buffer unit configured to store a first substrate and a second substrate on which an organic emission material has been deposited;
a first cluster module comprising a first cluster and a second cluster, the first cluster being connected to the first buffer unit and comprising a plurality of first deposition chambers, and the second cluster being connected to the first cluster and comprising a plurality of second deposition chambers; and
a second cluster module comprising a third cluster and a fourth cluster, the third cluster being connected to the second cluster and comprising a plurality of third deposition chambers, and the fourth cluster being connected to the third cluster and comprising a plurality of fourth deposition chambers,
wherein the first buffer unit is configured to alternately input the first substrate and the second substrate to the first cluster such that a first deposition material is deposited on the first substrate in one of the first deposition chambers and the first deposition material is deposited on the second substrate in one of the second deposition chambers.

13. The thin film encapsulation manufacturing device of claim 12, wherein a second deposition material is deposited on one of the first substrate and the second substrate in one of the third deposition chambers, and the second deposition material is deposited on the other one of the first substrate and the second substrate in one of the fourth deposition chambers.

14. The thin film encapsulation manufacturing device of claim 12, wherein the first substrate passes through the second cluster after being deposited in the first cluster, and the second substrate is deposited in the second cluster after passing through the first cluster.

15. A method of manufacturing a thin film encapsulation unit, the method comprising:
loading a first substrate and a second substrate on which an organic emission material is deposited into a first buffer unit;
discharging the first substrate from the first buffer unit to a first cluster, and then, discharging the second substrate from the first buffer unit to the first cluster;
discharging the first substrate from the first cluster after a first deposition material is deposited on the first substrate in a first deposition chamber of the first cluster, and passing the second substrate through the first cluster;
loading the first substrate and the second substrate discharged from the first cluster into a second buffer unit;
discharging the first substrate and the second substrate from the second buffer unit to a second cluster; and
discharging the second substrate from the second cluster after the first deposition material is deposited on the second substrate in a second deposition chamber of the second cluster, and passing the first substrate through the second cluster.

16. The method of claim 15, further comprising determining whether or not a deposition process in the first deposition chamber is congested before discharging the first substrate or the second substrate from the first buffer unit,
wherein, when the deposition process in the first deposition chamber is congested, the first buffer unit stops discharging the first substrate and discharges the second substrate.

17. The method of claim 15, further comprising determining whether or not a deposition process in the second deposition chamber is congested before discharging the first substrate or the second substrate from the second buffer unit,
wherein, when the deposition process in the second deposition chamber is congested, the second buffer unit stops discharging the second substrate and discharges the first substrate.
